(19) United States
(12) Patent Application Publication
(10) Pub. No.: US 2006/0038293 A1
(43) Pub. Date: Feb. 23, 2006

(54) Inter-metal dielectric fill

(76) Inventors: Neal R. Rueger, Boise, ID (US); Chris W. Hill, Boise, ID (US); Zailong Bian, Boise, ID (US); John A. Smythe III, Boise, ID (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/924,707

(22) Filed: Aug. 23, 2004

(51) Int. Cl. H01L 23/52; H01L 23/48

(52) U.S. Cl. 257/751; 257/760; 257/758; 257/750

(57) ABSTRACT

An inter-metal dielectric (IMD) fill process includes depositing an insulating nanolaminate barrier layer. The nanolaminate is preferably an oxide liner formed by using an alternating layer deposition process. The layer is highly conformal and is an excellent diffusion barrier. Gaps between metal lines are filled using high density plasma chemical vapor deposition with a reactive species gas. The barrier layer protects the metal lines from shorts between neighboring layers. The resulting structure has substantially uneroded metal lines and an insulating IMD fill.

### BACKGROUND OF THE INVENTION

1. Field of the Invention

The present invention relates to the field of semiconductor fabrication, specifically to electrical insulation of conductive structures.

2. Description of the Related Art

Integrated circuits are growing increasingly dense. In particular, dynamic random access memory (DRAM) gets more compact every generation. DRAM is a type of computer memory that has a wide array of applications. DRAM works by storing each bit in a memory cell, which is within a greater memory array. Each memory cell is primarily comprised of a capacitor and a transistor. The charge stored on the capacitor represents the value of the memory bit.

While the shrinking of DRAM has had significant advantages in terms of speed and power, it also has the effect of making design challenging. One example of this is the problem of isolation of metal lines. Inter-metal dielectric (IMD) electrically isolates neighboring layers and structures. In many cases, this metal is aluminum, which brings certain advantages and disadvantages. Integrated circuits have long employed aluminum deposition, and it is thus a well-known process. However, aluminum as a metal exhibits some negative properties. First of all, aluminum has a melting point of 660.32° C., whereas other metals have higher melting points. For example, copper has a substantially higher melting point of 1084.62° C. Additionally, the conduction and charging properties of aluminum also make IMD fill of aluminum lines challenging for plasma based deposition processes.

Inter metal dielectric fill of metallization structures is very important to the stability of the integrated circuit. Accordingly, there is a need for improved processes and materials for IMD fill.

### SUMMARY OF THE INVENTION

In one aspect of the invention, a metallization structure in an integrated circuit device is provided. The metallization structure comprises a plurality of metal lines on a substrate, an insulating nanolaminate barrier layer over the metal lines, and an inter-metal dielectric over the nanolaminate layer.

In another aspect of the invention, an integrated circuit is provided. The circuit comprises a metal layer with a plurality of metal lines and a plurality of gaps, a conformal metal-containing oxide liner over the metal lines and the gaps, and an oxide fill material over the conformal metal-containing oxide liner.

In another aspect of the invention, a method of insulating metal lines is provided. The method comprises forming a metal layer and patterning the metal layer to form metal lines. An alternating layer deposition liner is deposited over the metal lines and gaps between the metal lines. The gaps are filled with an inter-metal dielectric (IMD) fill material.

In another aspect of the invention, a method of insulating a plurality of metal lines is provided. The method comprises depositing a barrier layer over the metal lines and gaps between the metal lines. The gaps between the metal lines are filled with an inter-metal dielectric material using high density plasma chemical vapor deposition with a fluorinated source, a silicon source, and an oxygen source.

In another aspect, a method of connecting components on an integrated circuit is provided. A plurality of metal lines is formed. The metal lines are lined with a silicon oxide material, which contains a metal. A plurality of gaps between the metal lines is filled with an insulating dielectric material.

### BRIEF DESCRIPTION OF THE DRAWINGS

FIG. 1 is a schematic, cross-sectional side view of a metal layer with unfilled gaps between the metal lines.

FIG. 2 is a schematic, cross-sectional side view of a metal layer with filled gaps between the metal lines without a barrier layer illustrating potential process damage.

FIG. 3 is a schematic, cross-sectional side view of a metal layer with unfilled gaps between the metal lines with a barrier layer.

FIG. 4 is a schematic, cross-sectional side view of a metal layer with filled gaps between the metal lines with a barrier layer.

### DETAILED DESCRIPTION OF THE PREFERRED EMBODIMENT

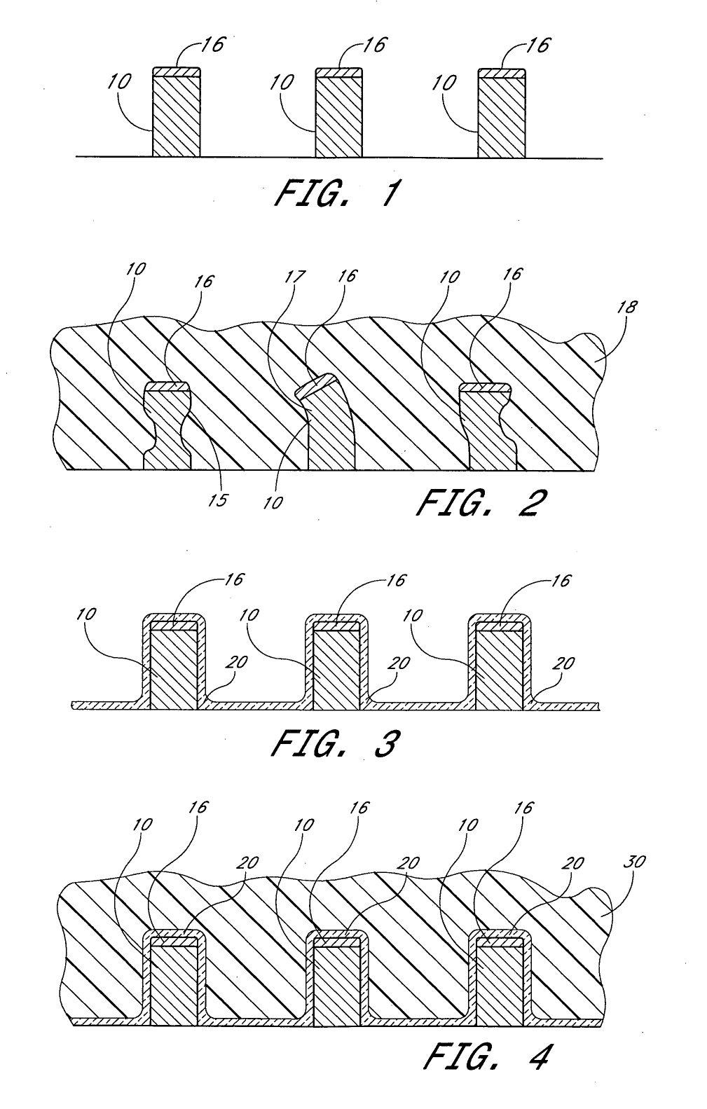

IMD fill is an important process to enable the use of metal lines in integrated circuit (IC) device. The metal lines are used to connect various electrical components on the IC. An example of several metal lines is seen in FIG. 1. A preferred material for the metal lines is aluminum, but other metals such as tungsten (W), titanium nitride (TiN), and tungsten silicide (WSi) can be used. In a preferred embodiment, the aluminum lines have nitride, preferably TiN, caps in order to protect the upper portion of the line. The TiN caps serve as an anti-reflective coating during the formation of the metal lines. The metal lines are preferably on a substrate comprising a semiconductor material or an insulating layer, such as a lower IMD-filled metal line. The substrate could be structures formed within or over a semiconductor wafer.

Metal lines are preferably formed by first depositing a blanket layer of the selected metal. The metal is then patterned, such as by conventional photolithography. The pattern is then etched into the metal, forming the metal lines. Preferably, contacts to the metal line are made in the layer beneath the metal line. The metal lines are preferably between 80 nm and 140 nm apart.

FIG. 1 shows a patterned metal layer with unfilled gaps between the metal lines. Preferably, the metal lines are aluminum. The metal lines 10 are preferably covered by titanium nitride caps 16 in order to protect the lines 10, especially the surfaces of the lines 10, and to act as an anti-reflective coating.

FIG. 2 shows the metal layer after a high density plasma chemical vapor deposition (HDP-CVD) of a silicon oxide filler 18. The metal lines 10 can become either eroded or etched during the plasma deposition, which can make the lines unusable. Additionally, due to the conductive nature of the metal lines, “ion steering” can occur. Ion steering results from differing charge distributions on conductive and non-conductive elements. The ions in the plasma are either repelled or attracted by the charge. Ion steering can result in damage to the lower sidewalls of the metal lines 10. Specifically, it can cause re-entrant etching or sputtering in the lower portion of the metal lines. An example of this is seen in FIG. 2; where a metal line 15 illustrates re-entrant etching of a metal line. Other damage is also apparent in FIG. 2. A metal line 17 appears to be uneven. This type of damage can occur due to melting of the metal.

The HDP-CVD process can also cause sidewall sputter and redeposition between the metal lines, especially when aluminum is used in the metal line. This can lead to short circuits between lines as well as to the formation of voids in the fill material.

To alleviate these problems, in the preferred embodiments, an insulating liner, preferably an oxide-based insulating nanolaminate, is deposited on the metal line, as seen in FIG. 2. The metal line is then filled using a CVD process, preferably a plasma enhanced or assisted process, particularly HDP-CVD.

The Liner

In a preferred embodiment seen in FIG. 3, the metal lines 10 and the metal nitride caps 16 are covered by a thin insulating oxide liner 20. In a preferred embodiment the liner 20 contains aluminum. The top and the side surfaces of the metal elements are preferably covered by the liner, as well as the substrate between the metal lines. In one embodiment, the liner is a nanolaminate of bilayers comprising a thin layer of aluminum oxide and a thicker layer of silicon oxide.

An exemplary process for forming such a layer is described in the article by Hausmann, et. al., Rapid Vapor Deposition of Highly Conformal Silica Nanolaminates, Science, Vol. 298, pg 402-406. That article, the disclosure of which is incorporated by reference herein, describes the formation of a nanolaminate alumina-doped silica glass in a process termed alternating layer deposition. The nanolaminate layer has good step coverage, which reduces the likelihood of the creation of voids between the metal lines. In this process, a metal precursor is first adsorbed onto the surface of a substrate. The metal is then used as a catalyst for the deposition of silicon oxide.

In one embodiment, the liner is formed using vapor doses of an aluminum precursor TMA (trimethylaluminum (Al(CH₃)₃)) and TBOS (tris(tert-butoxy)silanol [(ButO)₃SiOH]). Other aluminum compounds that have similar chemical properties can also be used in place of TMA. One example is aluminum dimethylamide (Al₂(N(CH₃)₂)₆). Other sources, preferably organic silicon sources, can also be used. These materials are preferably pulsed alternatively. Other metals, such as hafnium and lanthanum, and their precursors can also be used to form the liner. The metal in the precursor preferably catalyzes deposition of silicon oxide using the TBOS precursor.

One embodiment of the liner is deposited through a two-part reaction. This deposition process uses the aluminum of the first precursor as a catalyst for the deposition of the silicon oxide. In a first chemisorption reaction, the TMA chemisorbs onto the surface of the substrate. The TMA, or other organic metal compound, will provide a metal that will act as a catalyzing agent for the decomposition of an organic silicon precursor. Approximately a monolayer, or preferably between about 5 Å and 40 Å, of the aluminum compound is chemisorbed onto the surface of the metal lines and the surrounding substrate in each deposition cycle. TMA is broken down into methylaluminum (AlCH₃), which is bound to the surface of the preceding layer. Methane (CH₄) is produced and released during this reaction.

When the TBOS is introduced into the chamber, it reacts with the methylaluminum and bonds to the substrate surface through the aluminum atoms. The reaction releases methane and forms a siloxane polymer bound to the surface through the aluminum atom. The TBOS can diffuse through the siloxane polymer, which allows the aluminum to catalyze additional TBOS molecules into siloxane polymer. The rate is limited by the catalytic conversion of TBOS to siloxane polymer.

The reaction is self-limiting because of the cross-linking of the siloxane polymer. The cross-linking reactions connect the siloxane polymer chains. The connection of the polymer chains causes the polymer layer to gel and solidify to form the silica layer. Once the silicon oxide layer is formed, the TBOS cannot diffuse to reach the aluminum atoms. In this manner, the reaction cycle is completed and the silicon oxide growth is limited. The saturation of the silicon oxide growth allows for very conformal layers with good step coverage.

The deposition of the silicon oxide using TBOS uses the aluminum compound on the surface as a catalyst. The remaining aluminum can account for between about 0.5 atomic % and 5 atomic % of the layer, more preferably between 2 atomic % and 4 atomic %. While there is no oxidant in the exemplary process other than the TBOS, the aluminum is generally oxidized in the reaction. The aluminum is preferably in very thin aluminum oxide layers at the bottom of each silicon oxide layer in the nanolaminate. However, it is not clear if the aluminum oxide that is formed is stoichiometric (e.g. Al₂O₃). The aluminum-based layer is approximately a monolayer thick, substantially thinner than the silicon oxide layer. The thickness of the aluminum oxide layer is preferably between about 1 Å and 10 Å, more preferably between about 1 Å and 3 Å. While the remaining aluminum can have a negative effect in some applications, the aluminum can be beneficial for the liner because of the diffusion barrier properties of aluminum oxide. The aluminum remains bound to the surface of either the underlying substrate or the preceding silicon oxide layer.

While the deposition is preferably accomplished in a chamber similar to an atomic layer deposition (ALD) and is a self-limiting process like ALD, the alternating layer deposition preferably deposits significantly more than a monolayer in each cycle. A typical monolayer of silicon oxide is approximately 3.7 Å, but this deposition process can deposit between about 10 Å and 300 Å per cycle, depending on flow rates and temperature in the chamber. The deposition rate is optimized at about 240° C., but conformality and step coverage can be improved using higher substrate temperatures. As the deposition rate of silicon oxide decreases, a greater percentage of one bilayer (e.g. a silicon oxide layer and a thin aluminum based layer) is the aluminum-based layer. The aluminum layer's thickness does not substantially change as the temperature or other variables change, but the silicon oxide deposition rate and consequently the thickness will change.

Layers grown in this manner generally grow linearly to the number of cycles, assuming the temperature and flow rates remain constant. This layer, also known as a pulsed dielectric layer (PDL), consists of micro-layers of aluminum oxide and silicon oxide. The layers are alternating between aluminum oxide and silicon oxide. Like ALD, the self-limiting nature of this process ensures very conformal and even layers. Additionally, since vapor flow is not a consideration as it is in CVD processes, thickness is consistent throughout the film.

In a preferred embodiment, the temperature of the substrate is preferably between about 175° C. and 375° C., more preferably between about 300° C. and 350° C. In a more preferred embodiment, between about 20 Å and 120 Å is deposited in each cycle. In a preferred embodiment, between about 1 and 10,000 cycles are run, more preferably between about 2 and 100 cycles, and most preferably between about 3 and 50 cycles. Preferred thickness of the layer is between about 15 Å and 1000 Å, more preferably between about 30 Å and 250 Å. The self-limiting nature of the deposition process ensures very conformal and even layers since perfectly uniform temperature and vapor flow are not required to produce uniform thickness.

The liner 20 can be seen in FIG. 3 over the metal lines 10 and the nitride caps 16 of FIG. 1. The liner has several purposes in the fill process. First, it serves as a mechanical barrier to erosion during the HDP-CVD fill process. The liner 20 also serves as a barrier to diffusion of materials (e.g. fluorine) from the fill material into the metal. Additionally, the liner 20 electrically insulates the metal lines to minimize ion steering that can damage the metal lines.

Chemical Vapor Deposition Inter-Metal Dielectric Fill

The IMD fill of the gaps between the metal lines is preferably accomplished using a chemical vapor deposition (CVD) process. In a preferred embodiment, a plasma enhanced CVD (PECVD) process is used, more preferably a HDP-CVD process is used. PECVD uses one or more gaseous reactants to form a solid layer on a substrate. PECVD processes are enhanced by the use of highly reactive plasma products, and can deposit at lower temperatures than other forms of CVD. Additionally, PECVD process can provide more planar deposition and better gap fill. HDP-CVD reactors are defined by the high density of the plasma that is generated through use of higher power in the chamber. Several suitable HDP-CVD reactors can be used; an example is Applied Materials' Ultima HDP-CVD series of reactors. Preferably, the inductive power is between about 500 W and 7000 W, more preferably between about 1000 W and 6000 W. The bias power is preferably between about 50 W and 4000 W, more preferably between about 150 W and 3000 W. Preferably, the pressure is between 1 mTorr and 40 mTorr, more preferably between about 5 mTorr and 30 mTorr.

HDP-CVD is sometimes used to deposit silicon oxide in trench type structures. An example of this is described in U.S. Pat. No. 6,129,819 issued to Shan et. al., which is incorporated by reference herein. HDP-CVD provides a single-step, cost-effective solution for gap filling with a high-quality dielectric material. HDP-CVD has become more popular as the size of devices has continued to shrink, especially with the growing use of the 0.10 μm node. Due to HDP-CVD's properties of sidewall sputtering and bottom-up filling, it is useful for filling trenches and vias. However, problems can arise with etching and sidewall redeposition, leaving an uneven surface

In a preferred embodiment, a fluorinated gas species is added to the HDP-CVD process. Possible fluorine sources include fluorine (F₂), nitrogen fluoride (NF₃), and silicon fluoride (SiF₄). The addition of fluorine to the plasma at low flow pressures gives the fill a reactive etch component to the deposition process and helps planarize the deposited material. Additionally, the addition of fluorine lowers the dielectric constant (k-value) of the dielectric fill material.

Silane (SiH₄) and oxygen (O₂) are commonly used precursors of silicon dioxide from HDP-CVD. The reactive species-containing precursor is used at relatively low flow rates. In an exemplary embodiment, the SiH₄ flow rate is 100 sccm, the oxygen flow rate is 170 sccm, and the fluorine precursor, NF₃, has a flow rate of 60 sccm. Preferably, the substrate surface temperature for the HDP-CVD process for IMD fill is between about 300° C. and 700° C., more preferably between about 350 C and 600° C. When using aluminum as the metal for the metal lines, the substrate temperature needs to be kept lower. Preferably, the substrate surface temperature for the HDP-CVD process for IMD fill between aluminum lines is between about 300° C. and 475° C., more preferably between about 325° C. and 400° C. Additional parameters, such as the length of the deposition process are dependent upon features of the metal line. Thickness of the fill is preferably determined by the characteristics of the metal lines. When the metal lines are relatively close, the thickness is preferably at least half of the distance between metal lines to provide gap fill. For example, if the distance between the metal lines is about 200 nm, the thickness of the IMD fill material is preferably greater than 100 nm, more preferably greater than 150 nm. The fill material over one metal line will meet the fill material over the neighboring metal line. However, when gaps between metal elements are particularly wide, the gap will be filled by fill of a thickness equal to or greater than the thickness of the metal layer. Excess material can be removed through processing steps such as chemical mechanical polishing (CMP). These parameters can be varied significantly without exceeding the scope of the disclosure.

In a preferred embodiment, the dielectric will contain a small amount of fluorine or carbon after the deposition fill process is complete. This will lower the k value of the dielectric material. Preferably, the fluorine concentration by atomic percentage in the IMD fill material is between about 4% and 18%, more preferably between about 9% and 12%.

In one embodiment, carbon is used to lower the k value of the fill material. This carbon can be from an organic silicon precursor or added separately at low flow rates. The carbon precursor can be used with or without the fluorine. When carbon containing gases are used, preferable concentration levels of carbon by atomic percentage in the IME fill material is between about 4% and 18%, more preferably between about 9% and 12%.

Gases can be used in several systems to add a reactive etch component to the deposition process. While HDP-CVD is used in a preferred embodiment, other deposition methods can be used. For example, plasma enhanced CVD (PECVD) and traditional CVD can also be used. Skilled practitioners will appreciate that features of the deposition process of the insulating fill material can be altered without exceeding the scope of the disclosure.

Structure

In a preferred embodiment as seen in FIG. 4, the metallization layer will comprise metal lines 10. The metal lines are preferably aluminum, but could also be tungsten, titanium nitride, or tungsten silicide. A protective liner is then conformally deposited over the metal lines. The protective layer is preferably a thin layer of a silicon oxide based material 20. The silicon oxide based material preferably contains a metal that was used to catalyze the deposition of the silicon oxide. In a preferred embodiment, the protective layer is an insulating nanolaminate containing layers of silicon oxide substantially thicker than a monolayer. Aluminum is dispersed throughout the silicon oxide, preferably concentrated between the layers of the nanolaminate film. The aluminum content in this silicon oxide based liner is preferably between about 0.5% and 5%, by atomic percentage, more preferably between about 2% and 4%. The protective layer is preferably between about 15 Å and 1000 Å, more preferably between about 30 Å and 250 Å.

The metallization structure is filled with a dielectric material 30 to isolate it from other neighboring conductive elements. Preferably, the fluorine concentration by atomic percentage in the IMD fill material is between about 4% and 18%, more preferably between about 9% and 12%. After filling the gaps between the metal lines, the structure can also be subjected to further processing steps, such as a CMP step.

The preferred oxide liner protects the metal lines from damage that the CVD oxide fill process could cause. Thus, the metal lines will not be substantially etched by the CVD oxide fill process. Additionally, the inclusion of fluorine reactive species in the HDP-CVD process will inhibit the formation of voids between the metal lines.

Although the invention has been described in terms of a certain preferred embodiment and suggested possible modifications thereto, other embodiments and modifications may suggest themselves and be apparent to those of ordinary skill in the art are also within the spirit and scope of this invention. Accordingly, the scope of this invention is intended to be defined by the claims which follow.

We claim:

1. An insulated metallization structure in an integrated circuit comprising a plurality of metal lines on a substrate;
an insulating nanolaminate barrier liner over the metal lines;
an inter-metal dielectric material over the nanolaminate layer.

2. The structure of claim 1, wherein the metal lines comprise aluminum.

3. The structure of claim 1, wherein the metal lines comprise tungsten.

4. The structure of claim 1, wherein the metal lines comprise titanium nitride.

5. The structure of claim 1, wherein the metal lines comprise tungsten silicide.

6. The structure of claim 1, further comprising a nitride cap on the metal lines.

7. The structure of claim 1, wherein the nanolaminate barrier layer comprises an alternating layer deposition deposited material.

8. The structure of claim 1, wherein the nanolaminate barrier layer comprises a silicon oxide layer with an aluminum content of between about 0.5 atomic % and 5 atomic %.

9. The structure of claim 1, wherein the nanolaminate barrier layer comprises a silicon oxide layer with an aluminum content of between about 2 atomic % and 4 atomic %.

10. The structure of claim 1, wherein the nanolaminate barrier layer comprises a plurality of bilayers, wherein a cycle layer comprises a thin layer of aluminum oxide beneath a layer of silicon oxide.

11. The structure of claim 10, wherein the nanolaminate barrier layer comprises between about 2 and 100 bilayers.

12. The structure of claim 11, wherein the nanolaminate barrier layer comprises between about 3 and 50 bilayers.

13. The structure of claim 1, wherein the nanolaminate barrier layer comprises a nanolaminate layer of between about 15 Å and 1000 Å.

14. The structure of claim 13, wherein the nanolaminate barrier layer comprises a nanolaminate layer of between about 30 Å and 250 Å.

15. The structure of claim 1, wherein the inter-metal dielectric comprises a chemical vapor deposition (CVD) deposited oxide.

16. The structure of claim 15, wherein the inter-metal dielectric comprises a plasma enhanced chemical vapor deposition (PECVD) deposited oxide.

17. The structure of claim 16, wherein the inter-metal dielectric comprises a high density plasma chemical vapor deposition (HDP-CVD) deposited oxide.

18. The structure of claim 17, wherein the HDP-CVD deposited oxide comprises silicon oxide with a fluorine content by atomic percentage of between about 4% and 18%.

19. The structure of claim 18, wherein the HDP-CVD deposited oxide comprises silicon oxide with a fluorine content by atomic percentage of between about 9% and 12%.

20. The structure of claim 17, wherein the HDP-CVD deposited oxide comprises silicon oxide with a carbon content by atomic percentage of between about 4% and 18%.

21. The structure of claim 20, wherein the HDP-CVD deposited oxide comprises silicon oxide with a carbon content by atomic percentage of between about 9% and 12%.

22. An integrated circuit comprising;
a metal layer with a plurality of metal lines and having a plurality of gaps between adjacent lines;
a conformal metal-containing oxide liner over the metal lines and the gaps; and
an oxide fill material over the conformal metal-containing oxide liner.

23. The integrated circuit of claim 22, wherein the conformal metal-containing oxide liner comprises a silicon oxide containing a catalyzing agent for decomposition of an organic silicon precursor.

24. The integrated circuit of claim 23, wherein the conformal metal-containing oxide liner comprises an oxide layer containing aluminum.

25. The integrated circuit of claim 22, wherein the conformal metal-containing oxide liner comprises an insulating nanolaminate.

26. The integrated circuit of claim 22, wherein the oxide fill material comprises an HDP-CVD oxide.

27. The integrated circuit of claim 22, further comprising a plurality of dynamic random access memory (DRAM) cells.

28. The integrated circuit of claim 22, wherein the circuit comprises a computer memory device.

29. A method of filling gaps between metal lines comprising:
forming a metal layer;
patterning the metal layer to form a plurality of metal lines and a plurality of gaps between the metal lines;
depositing an alternating layer deposition liner over the metal lines and the gaps between the metal lines; and
filling the gaps between the metal lines with an inter-metal dielectric (IMD) fill material.

30. The method of claim 29, further comprising performing a chemical mechanical polishing process on the fill material.

31. The method of claim 29, wherein forming the metal layer comprises forming an aluminum layer.

32. The method of claim 29, wherein depositing the liner comprises chemisorbing a catalyst over the metal lines and the gaps between the metal lines; and
catalyzing a vapor deposition over the catalyst.

33. The method of claim 32, wherein catalyzing the vapor deposition comprises a self-limiting process.

34. The method of claim 32, further comprising repeating chemisorbing the catalyst and catalyzing the vapor deposition.

35. The method of claim 32, wherein chemisorbing the catalyst comprises using an organic aluminum compound as a precursor.

36. The method of claim 35, wherein using an organic aluminum precursor comprises using trimethylaluminum (Al(CH₃)₃) as an aluminum precursor.

37. The method of claim 35, wherein using an organic aluminum precursor comprises using aluminum dimethylamide (Al₂(N(CH₃)₂)₆) as an aluminum precursor.

38. The method of claim 32, wherein catalyzing the vapor deposition comprises using an organic silicon precursor.

39. The method of claim 38, wherein depositing the liner comprises using (tris(tert-butoxy)silanol [(ButO)₃SiOH]) as a silicon source for alternating layer deposition.

40. The method of claim 29, wherein depositing the liner comprises using alternating layer deposition at a temperature of between about 175° C. and 375° C.

41. The method of claim 40, wherein depositing the liner comprises using alternating layer deposition at a temperature of between about 300° C. and 350° C.

42. The method of claim 29, wherein depositing the liner comprises depositing between about 15 Å and 1000 Å.

43. The method of claim 42, wherein depositing the liner comprises depositing between about 30 Å and 200 Å.

44. The method of claim 29, wherein depositing the liner comprises using between 1 and 10,000 cycles of alternating layer deposition.

45. The method of claim 44, wherein depositing the liner comprises using between 1 and 100 cycles of alternating layer deposition.

46. The method of claim 45, wherein depositing the liner comprises using between 2 and 50 cycles of alternating layer deposition.

47. The method of claim 29, wherein filling the metal line comprises using a high density plasma chemical vapor deposition (HDP-CVD) process.

48. A method of insulating a plurality of metal lines comprising:
depositing a barrier layer over the metal lines and a plurality of gaps between the metal lines;
filling the gaps between the metal lines with an inter-metal dielectric material, wherein filling the gaps comprises using high density plasma chemical vapor deposition (HDP-CVD) with a fluorine source, a silicon source and an oxygen source.

49. The method of claim 48, wherein using HDP-CVD comprises using separate precursors for the fluorine source, the silicon source and the oxygen source.

50. The method of claim 48, wherein depositing the barrier layer comprises depositing a nanolaminate layer.

51. The method of claim 50, wherein depositing the nanolaminate layer comprises using an alternating layer deposition process.

52. The method of claim 48, wherein depositing the barrier layer comprises depositing a silicon oxide layer containing aluminum.

53. The method of claim 48, wherein filling the gaps comprises using a fluorinated gas selected from the group comprising nitrogen fluoride (NF₃), silicon fluoride (SiF₄), and fluorine (F₂).

54. The method of claim 48, wherein filling the gaps comprises using silane (SiH₄) as the silicon precursor.

55. The method of claim 48, wherein filling the gaps comprises using oxygen (O₂) as the oxygen source.

56. A method of connecting components on an integrated circuit comprising
forming a plurality of metal lines;
lining the metal lines with a silicon oxide material, wherein the silicon oxide material contains a metal; and
filling a plurality of gaps between the metal lines with an insulating dielectric material.

57. The method of claim 56, wherein filling the gaps comprises using a plasma enhanced chemical vapor deposition process.

58. The method of claim 57, wherein filling the gaps comprises using a high density plasma chemical vapor deposition (HDP-CVD) process.

59. The method of claim 58, wherein using the HDP-CVD process comprises using an inductive power level of between about 500 W and 7000 W.

60. The method of claim 58, wherein using the HDP-CVD process comprises using a bias power level of between about 50 W and 4000 W.

61. The method of claim 58, wherein using the HDP-CVD process comprises using a pressure level of between about 1 mTorr and 40 mTorr.

62. The method of claim 58, further comprising using a fluorinated gas in the HDP-CVD process.

63. The method of claim 56, wherein lining the metal lines comprises alternating vapor doses of a catalytic metal precursor and an organic silicon precursor.

64. The method of claim 63, wherein alternating vapor doses comprises alternating vapor doses of trimethylaluminum (Al(CH₃)₃) and (tris(tert-butoxy)silanol [(ButO)₃SiOH]).

65. The method of claim 63, wherein alternating vapor doses comprises using a temperature of between about 175° C. and 375° C.

66. The method of claim 65, wherein alternating vapor doses comprises using a temperature of between about 300° C. and 350° C.
